(19) United States
(12) Patent Application Publication
(10) Pub. No.: US 2011/0148429 A1
(43) Pub. Date: Jun. 23, 2011

(54) DC Testing Integrated Circuits

(76) Inventor: Ronald K. Minemier, Tempe, AZ (US)

(21) Appl. No.: 12/643,105

(22) Filed: Dec. 21, 2009

(51) Int. Cl. G01R 31/02

(52) U.S. Cl. 324/537

(57) ABSTRACT

In accordance with some embodiments, voltage testing, including input and output voltage levels, may be tested in an integrated circuit without using an external tester in some embodiments. In some cases, active loads may be provided on chip for DC testing. In addition, a comparator may be used to compare an input voltage on an interconnection to a reference voltage to determine whether the voltage levels are correct and the extent to which the voltage levels exceed the designer's specification.

### BACKGROUND

This relates generally to testing integrated circuits and, particularly, to DC testing of input and output voltages of integrated circuits.

Testing integrated circuits is a routine task to verify the quality of those circuits so that they meet design specifications. Testing can be done at different points during the manufacturing process of these products. A tester can be applied to the pads of an integrated circuit when it is at the wafer level or to the pins of the integrated circuit after it is formed in a package.

The DC tests that are conventionally done include input low voltage, input high voltage, output low voltage, and output high voltage. In addition, tests may be done to detect opens and shorts within the chip. Leakage testing may also determine whether or not charge is being dissipated by the integrated circuit.

Conventionally, the testing is done using a tester and, particularly, a channel card. The channel card is needed for each integrated circuit signal that is tested at the same time. Thus, the cost to simultaneously test a large number of integrated circuits is relatively high. In addition, the tester cost is substantial, as is the time associated with such testing.

After the product is in the field, DC testing is generally not viable because the manufacturer who assembles the chips into the completed products may not want to incur the expense of such a tester. Moreover, once the integrated circuit is secured to a board or other component, such testing is generally believed to be not feasible.

### BRIEF DESCRIPTION OF THE DRAWINGS

FIG. 1 is a circuit schematic for one embodiment of the present invention;

FIG. 2 is a flow chart for one embodiment of the present invention; and

FIG. 3 is a truth table for the control shown in FIG. 1 in accordance with one embodiment.

### DETAILED DESCRIPTION

In accordance with some embodiments of the present invention, circuitry may be provided in each integrated circuit that facilitates the DC testing of that circuit. Particularly, circuitry may be provided to enable input voltage low and high tests, output voltage low and high tests, shorts, opens, and leakage testing in some embodiments.

Moreover, it is possible for the customer who assembles products using the integrated circuit to also perform DC tests. Enabling testing after the integrated circuit has been assembled to other components may be advantageous. For example, it may enable a manufacturer to determine if the solder joint between the integrated circuit and another component is defective.

For the manufacturer of the integrated circuit, providing test features within the integrated circuit may facilitate testing, improve testing speed, and reduce testing cost in some embodiments. These advantages may arise because, in some embodiments, it is not necessary to have a channel card for each integrated circuit chip signal. Instead, multiple integrated circuits may be tested from a single external signal source. For some DC testing embodiments, there is no need to touch or contact the integrated circuit.

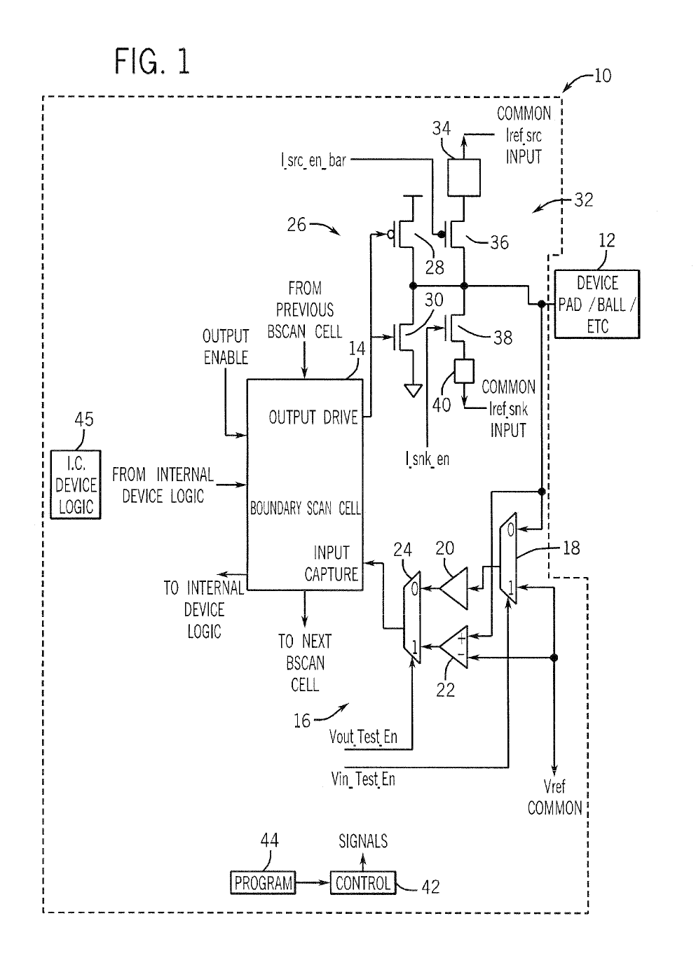

Referring to FIG. 1, an integrated circuit 10 may be any integrated circuit. The circuit includes integrated circuit device logic 45, that includes the functional integrated circuit components. Also provided on-chip are components to facilitate DC testing. One testing component may be a control 42. The control 42 may be hard wired logic or, in a software embodiment, a processor or controller that provides signals with the right timing to implement DC testing. In a software embodiment, a program 44 may be executed by the control that, in such case, may be a processor or controller. As a result, DC test control signals are provided, as indicated in FIG. 1.

On the outside of the integrated circuit 10, which may be packaged, is an interconnection 12. The interconnection 12 may be any electrical terminal, such as a solder ball or a pad, in the case of a wire bond connection. Typically, the integrated circuit 10 would have a large number of such interconnections 12 and associated test circuitry, but only one interconnection is shown for simplicity.

The integrated circuit 10 also has, for each interconnection 12, integrated components that are used for testing. These integrated components may include a boundary scan cell 14 to store and capture test information. The boundary scan cell 14 may receive inputs from a previous boundary scan cell (not shown) for another interconnection (not shown), and output enable signals from the internal device logic 45. The cell may send signals to the internal device logic 45 and to the next boundary scan cell (not shown) for another interconnection (not shown).

The boundary scan cell 14 may be coupled to a test mode driver 26. In one case, the driver may include a PMOS transistor 28 in series with an NMOS transistor 30, both of whose gates are driven by the output drive signal from the boundary scan cell 14. The node between the two transistors may be connected directly to the interconnection 12. Also coupled to the interconnection 12 is an active load circuit 32 including a pair of active loads 34 and 40 in one embodiment. The upper active load 34 is coupled to the interconnection 12 through a transistor 36. The gate of the transistor 26 may receive the source current enable bar I_src_en_signal (i.e. the inverse of the source current enable signal).

The output of the active load 34 may be a common current reference source input (Iref_Src). This is a signal provided to the control 42. The other active load 40 is coupled through a transistor 38, whose gate is driven by the current sink enable (I_snk_en) signal, again, generated by the control 42. The output of the active load 40 is the common current reference sink input (common Iref_snk), which signal is provided to control 42.

Each of the two integrated active loads enables a range of loading conditions to be applied to the integrated circuit device logic 45 to test a range of potential conditions. In some embodiments, these active loads may be implemented by current mirrors. In other embodiments, they may be implemented by circuits that mimic drivers in the device logic 45. They may differ from those drivers in that they do not need to do all of the functions of the real drivers, replicating only the current sourcing and sinking functions of the real drivers. Thus, the active loads may mimic the range of current sourcing and sinking done by a driver in the logic 45.

Because the active loads are integrated on board the integrated circuit 10, they need not be supplied from an external source, such as a tester or channel card. This allows an external source to test a large number of integrated circuits without having to provide a channel card for each tested circuit. Because the active loads 34 and 40 are formed by an integrated circuit process, they are economical. That is, they may be formed on the same integrated circuit die with the integrated circuit device logic 45, reducing cost.

Also connected to the interconnection 12 is an analog multiplexer 18 that receives an input from the interconnection 12, as well as from a variable voltage reference (Vref common). Depending on the Vin_Test_En signal that is applied by the control 42, one of either Vref common or the signal from the interconnection 12 is passed on to an input buffer 20 for the interconnection 12. The output of that buffer 20 is provided to a digital multiplexer 24. Also coupled to the digital multiplexer 24 is a comparator 22 whose non-inverting input is coupled to the interconnection 12 and whose inverting output is coupled to the reference voltage common.

Thus, one of these two voltages (the interconnection or reference voltage common) is passed by the multiplexer 24 based on the output test enable (Vout_Test_En) signal, also supplied by the control 42. The output of the multiplexer 24 is supplied to the boundary scan cell 14 input capture.

In some embodiments, the circuitry 16 may enable the determination of whether or not the input voltage is at its proper level, either low or high, and, further, to what extent it exceeds the specifications for low and high voltage. The extent to which the specification is exceeded may be determined by comparing, in comparator 22, the actual input voltage signal to the variable reference common voltage. The comparator determines whether the low input signal is lower than the specification and whether the high input signal is higher than the specification. The reference common may be, at one time, a low reference voltage and, at another time, a high reference voltage. In addition, it may be a selected one of a range of low or high voltages that are changed until the comparison suggests that, in the case of a low voltage, the voltage is no longer lower than the reference and, in the case of the high voltage, the voltage is no longer higher than the reference. This variable comparison enables a characterization of the extent by which the input high and low voltages exceed their specifications.

The multiplexer 18 is controlled by the test enable signal. When input test enable (Vin_Test_En) is enabled, then the reference common voltage is used and, in all other cases, the input from the interconnection 12 is simply passed on through the buffer 20 without being delayed by the comparator 22. This signal selection allows normal interconnection signals, when there is no test mode being run, to be substantially unaffected by the on-board test circuitry. Similarly, if output test enable is disabled, the interconnection signal passes through the second multiplexer 24. Otherwise, the signal from the comparator may be used.

In some embodiments, all or any number of the interconnections of an integrated circuit may use the same active loads 34 and 40 so that data may be shifted out more quickly than would otherwise be the case.

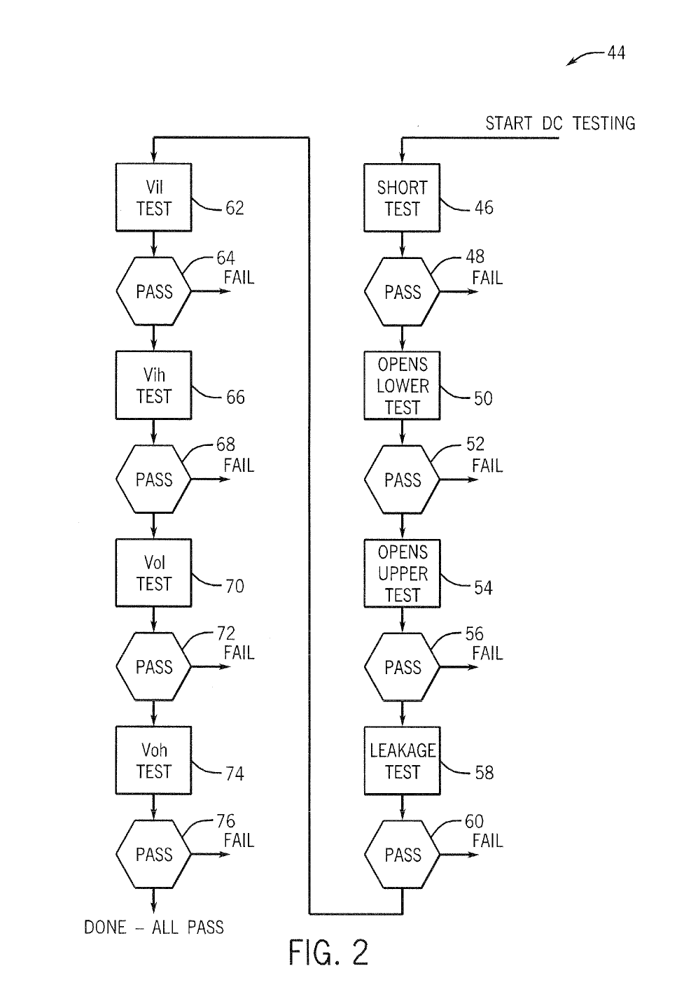

Referring to FIG. 2, a sequence implemented by the control 42 is illustrated. In some embodiments, it may be implemented in software or program 44, in which case the software may constitute instructions stored in a computer readable medium, such as the control 42. Those instructions may then be executed by a processor, controller, or computer, such as the control 42. In other embodiments, the sequence may be implemented in hard wired logic.

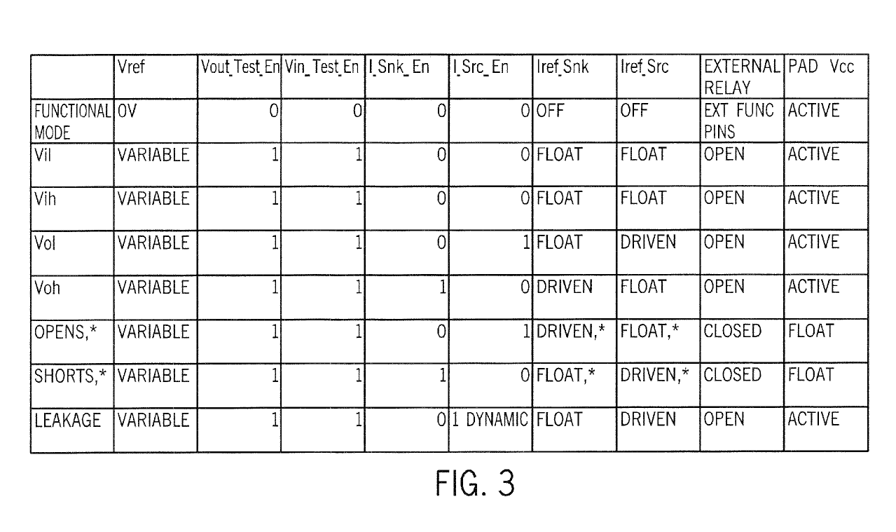

The test sequence, shown in FIG. 2, is implemented using the truth table shown in FIG. 3, in one embodiment. The truth table has columns which give the various signals that may be generated externally or by the control 42. The rows give the functions or tests that may be implemented in one embodiment. The first row is the functional mode wherein no testing is done and the integrated circuit device logic 45 performs its intended function.

The remaining rows are for various tests that may be run in test mode in some embodiments. In other words, some or all of those tests may be run using the signals indicated in the columns in one embodiment.

Initially, DC testing begins by enabling the appropriate signals from the control 42. For example, initially, a shorts test is implemented at block 46 and the appropriate signals are driven from the control 42.

For example, referring to FIG. 3, in order for the shorts test to be implemented, the reference voltage signal is driven appropriately. The output test enable, the input test enable, and the current sink signals are enabled, and the current source enable is low so current source enable bar is high. The current reference sink and the interconnection (i.e. pad) supply voltage Vcc are allowed to float. The current reference source is driven. The signals associated with an asterisk in FIG. 3 may be provided from an external source to the integrated circuit 10 using an external relay (not shown), selectively connected to a power plane or a ground plane. In the case of the shorts test the external relay is closed to provide an external signal, which is sunk if there is a short.

A check at 48 determines whether or not the shorts test fails. Both loads are operating. If the floating interconnection is pulled down, a low signal is captured by the boundary scan cell input capture. This indicates a short.

Then, an opens lower test is done at 50, basically using the methodology and the values set forth in FIG. 3. Again, the asterisks in the current reference sink and source columns indicate that these signals are switched externally to the integrated circuit 10. A decision is made about whether the interconnection passes the opens lower test at 52. The same procedure is followed in blocks 54 and 56 for the opens upper test.

Next, a leakage test may be done at 58 and the results compiled at 60. The leakage test is driven from the control 42 using the signals shown in FIG. 3 in the row labeled “Leakage.” The leakage test can be implemented in the same arrangement that also does the input/output, shorts, and opens tests. Generally, the leakage test may be done, in some embodiments, by simply driving a signal onto the logic device 45 and determining how fast that charge dissipates.

Thereafter, a current loaded (i.e. using an active load) input low voltage (vil) test is implemented (block 62 and 64). To implement this test, a reference voltage is driven, the output and input test enables are high and the current sink enable and current source are low (so current sink enable bar is high). The reference current sink floats, as does the reference source and the external relay is open, while the pad supply voltage is active. In such case, the comparator 22 may be utilized to determine whether or not the input voltage is within specifications and if it is better than the specification, and how much better it is. This may be done by driving different reference voltages to the comparator 22 until the input voltage is higher than the reference. This result is captured by the boundary scan cell. The boundary scan cell can also capture the last reference voltage supplied by the control. Based on the applied reference voltage, the improvement, if any, over the specification may be determined.

With respect to the input high voltage (vih), the values set forth in the table of FIG. 3 may be utilized and the same operation may be implemented, as indicated in blocks 66 and 68. With this test, the boundary scan cell captures the point when the input voltage is no longer higher than the varied reference voltage. Based on the applied reference voltage, the improvement, if any, over the specification may be determined.

Thereafter, the output low voltage (vol) test 70 is done and the results compiled at block 72. The output low voltage test uses the signals shown in FIG. 3 and does not use the comparator 22. Finally, the output high voltage test (voh) is done at blocks 74 and 76 using the truth table values shown in FIG. 3.

The reference voltage signal is a lower voltage for the input voltage low signal and the output voltage low signal and higher voltage for the input voltage high and the output voltage high signal. It may be the same voltage for the opens, shorts, and leakage tests.

References throughout this specification to “one embodiment” or “an embodiment” mean that a particular feature, structure, or characteristic described in connection with the embodiment is included in at least one implementation encompassed within the present invention. Thus, appearances of the phrase “one embodiment” or “in an embodiment” are not necessarily referring to the same embodiment. Furthermore, the particular features, structures, or characteristics may be instituted in other suitable forms other than the particular embodiment illustrated and all such forms may be encompassed within the claims of the present application.

While the present invention has been described with respect to a limited number of embodiments, those skilled in the art will appreciate numerous modifications and variations therefrom. It is intended that the appended claims cover all such modifications and variations as fall within the true spirit and scope of this present invention.

What is claimed is:

1. A method comprising:
providing an on chip active load for enabling current loaded voltage testing of an integrated circuit.

2. The method of claim 1 including providing a pair of on chip active loads and providing each active load with a selection transistor.

3. The method of claim 1 including coupling the active load to an external interconnection.

4. The method of claim 1 including comparing a voltage on an external interconnection to a reference voltage.

5. The method of claim 4 including comparing a voltage on the external interconnection to a plurality of reference voltages of different levels to determine the amount by which an input voltage is better than the input voltage level specified for the integrated circuit.

6. The method of claim 4 including enabling the comparison in a test mode and disabling the comparison during normal operation of the integrated circuit.

7. The method of claim 1 including using a boundary scan cell to record voltage test results.

8. An integrated circuit comprising:
an integrated circuit device logic; and
a testing circuit coupled to said device logic, said testing circuit including an on-chip active load to perform current loaded voltage testing of said device logic.

9. The circuit of claim 8 including a pair of on-chip active loads and a selection transistor for each active load.

10. The circuit of claim 8 including an external interconnection coupled to said active load.

11. The circuit of claim 10 including a comparator to compare an external interconnection voltage to a reference voltage.

12. The circuit of claim 11, said comparator to compare a voltage on said external interconnection to a plurality of reference voltages of different levels to determine the amount by which an input voltage is better than the input voltage level specified for the integrated circuit.

13. The circuit of claim 11 including a switch to enable a comparison during a test mode and to disable the comparison during normal operation of the integrated circuit.

14. The circuit of claim 8 including a boundary scan cell to record voltage test results.

15. An integrated circuit comprising:
device logic; and
an input voltage test circuit coupled to said device logic, said test circuit including a comparator to compare a reference voltage to a voltage input to said integrated circuit.

16. The circuit of claim 15, said comparator coupled to an external interconnection.

17. The circuit of claim 16, said comparator to compare a voltage on said external connection to a plurality of reference voltages of different levels to determine the amount by which an input voltage is better than the input voltage level specified for the integrated circuit.

18. The circuit of claim 15 including a switch to enable a comparison during a test mode and to disable the comparison during normal operation of the integrated circuit.

19. The circuit of claim 15, said test circuit including an active load.

20. The circuit of claim 19 including a pair of on-chip active loads and the selection transistor for each active load.
